(19) United States
(12) Patent Application Publication
(10) Pub. No.: US 2015/0305145 A1
(43) Pub. Date: Oct. 22, 2015

(54) JOINING METHODS FOR BULK METALLIC GLASSES

(71) Applicant: CORNING INCORPORATED, Corning, NY (US)

(72) Inventors: Satish Chandra CHAPARALA, Painted Post, NY (US); Lisa Anne MOORE, Corning, NY (US)

(21) Appl. No.: 14/646,217

(22) PCT Filed: Nov. 22, 2013
(86) PCT No.: PCT/US13/71433

§ 371 Date: May 20, 2015

Related U.S. Application Data
(60) Provisional application No. 61/731,146, filed on Nov. 29, 2012.

(51) Int. Cl. H05K 1/02; B23K 1/20; H01L 33/62; H01L 33/48; H01S 5/022; B23K 1/00; H05K 1/03

(52) U.S. Cl. CPC H05K 1/0274; B23K 1/0016; B23K 1/20; H05K 1/0306; H01L 33/486; H01S 5/02236; H01L 33/62

(57) ABSTRACT

Bulk metallic glass having at least one surface: applying a contact layer to at least a portion of the at least one surface of the bulk metallic glass; applying a diffusion barrier layer to the contact layer; applying a cap layer to the diffusion barrier layer to form a layered bulk metallic glass; and joining a material to the layered bulk metallic glass.

### CROSS-REFERENCE TO RELATED APPLICATIONS

This application claims the benefit of priority under 35 U.S.C. §119 of U.S. Provisional Application Ser. No. 61/731,146 filed on Nov. 29, 2012, the entire content of which is hereby incorporated by reference.

### FIELD

This disclosure relates to bulk metallic glasses and more particularly to methods of joining bulk metallic glasses useful for, for example, electronic packaging.

### BACKGROUND

Metallic glasses are metal alloys with non-crystalline microstructures. They are typically obtained by fast quenching from the molten state, which hinders crystallization. The preparation of metallic glass foil of an Au—Si alloy was first reported in 1960. Noble metal alloy metallic glass rods around 1 mm in diameter were reported in the mid-1970s to 1980s. Interest in metallic glasses increased rapidly in the late 1980s and 1990s, however, when bulk metallic glasses (BMGs), greater than a few mms in diameter, were successfully prepared from alloys of common metals.

The disordered atomic structure, lack of grain boundaries, and metastable state of metallic glasses leads to unique properties. Metallic glasses conduct electricity like conventional metals, but deform and fail brittly in tension, similar to conventional glasses. Typical carriers of plastic flow, dislocations, are not present leading to high tensile strengths and elastic limits but different kinds of failure modes than conventional metals. The formation of metallic glass composites, by either mixing in or precipitating a second phase within the glassy matrix, has been reported as a method for tuning the mechanical, thermal, and electrical properties of these materials.

Like conventional glasses, metallic glasses exhibit a glass transition temperature (Tg) and crystallize at a temperature (Tx) above Tg. Within this supercooled liquid region (SCLR, Tx-Tg), metallic glasses can be thermo-plastically formed into precise and complex shapes using methods similar to those used for conventional glasses—e.g. compression molding, blowing, embossing. They can also be cast directly into molds and quenched to a glassy state with very low shrinkage.

These properties of BMGS have made them attractive for applications in aerospace, naval, sports equipment, electronic packaging, MEMS and biomedical devices. In order to enable the applications in most of these fields, it would be advantageous to have joining technologies which enable two BMGs or BMGs and other classes of materials to be joined.

### SUMMARY

One embodiment is a method comprising:
providing a bulk metallic glass having at least one surface;
applying a contact layer to at least a portion of the at least one surface of the bulk metallic glass;
applying a diffusion barrier layer to the contact layer;
applying a cap layer to the diffusion barrier layer to form a layered bulk metallic glass; and
joining a material to the layered bulk metallic glass.

Another embodiment is a bulk metallic glass submount comprising:
a bulk metallic glass having at least one surface;
a contact layer on at least a portion of the at least one surface of the bulk metallic glass;
a diffusion barrier layer on the contact layer; and
a cap layer on the diffusion barrier layer.

One such joining technology which may be suitable for electronic packaging is disclosed here. Further disclosed is an application for BMGs in the fields of micro- or opto-electronics packaging. Some embodiments may provide substrates with good CTE match to GaN, while also having good thermal stability, chemical durability, and surface polish characteristics. Further advantages may be ease of package formability or significant cost savings due to reduced bill of materials and less process steps. This is advantageous because in some products, 70-80% of the cost is the bill of materials. If the application of the product is in consumer electronics where cost is a factor, BMG packaging may provide a significant advantage. Further, the BMG joining methods disclosed herein are compatible with standard soldering materials and process equipment.

A new joining process is disclosed and an application for bulk metallic glasses (BMGs). A method to join a semiconductor material or any other class of material with bulk metallic glass through soldering is also disclosed. The BMG can be coated with Cr—Ni followed by dull-sulfamate nickel and then with Au. The other material is recommended to have gold coating on the face that is going to be joined to the BMG. In some embodiments, the other face has the three layers described above. In semiconductors like GaAs, the metallization is Ti/Pt/Au, in InP, the metallization typically followed is Ti/W/W etc. There are several other combinations but these are examples. The solders can be pre-deposited on the substrate after the cap layer, for example, Au or the solder can be in the form of a pre-form layer.

The two materials can be joined using soldering. Solders that can be used include any conventional solders that are routinely used in micro-electronics and opto-electronics packaging such as eutectic Au—Sn, SAC305, SAC405 etc. The application disclosed is that the entire opto-electronics package can be formed from a BMG by taking advantage of the ease of formability of BMGs. This may eliminate the need for substrates, the need for processes to attach the substrates and sub-mounts, package bases etc. The whole package would be just one single piece comprised of a BMG.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTIONS OF THE DRAWINGS

FIG. 1 is an illustration of a prior art opto-electronics package.

FIG. 2 is an illustration of an opto-electronic package using a BMG made according to exemplary methods.

FIG. 3 is an illustration of an exemplary joining method.

FIG. 4 is a graph of an X-ray diffraction analysis of the polished surface of a BMG made according to exemplary methods.

FIG. 5 is an optical photograph of a GaAs chip soldered to a metalized or coated BMG substrate.

FIG. 6 is a backscattered electron image of a soldered interface showing adhesion of metallization layers and soldered to a BMG substrate.

### DETAILED DESCRIPTION

Reference will now be made in detail to various embodiments of glass-ceramics and their use in LED articles, examples of which are illustrated in the accompanying drawings. Whenever possible, the same reference numerals will be used throughout the drawings to refer to the same or like parts.

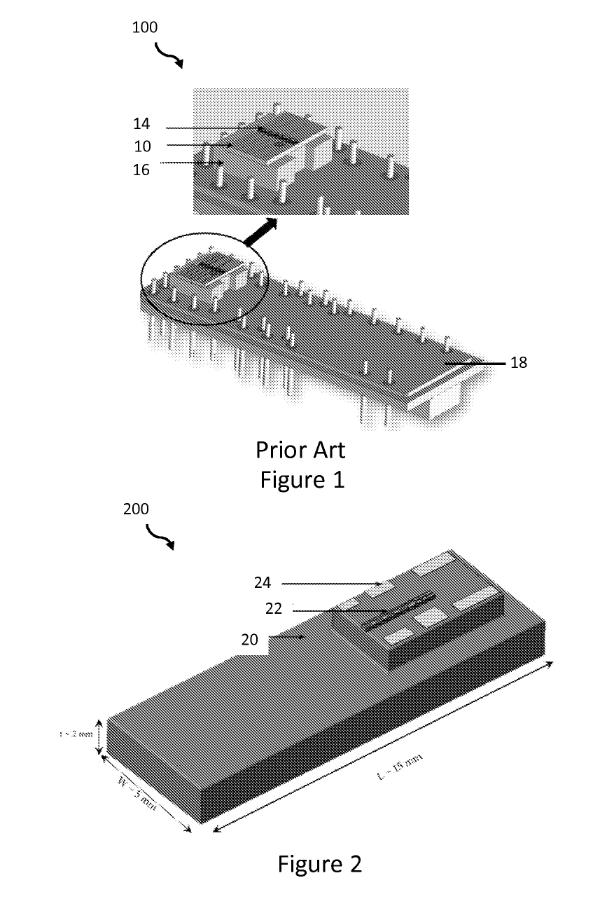

FIG. 1 is an illustration showing a prior art opto-electronics package 100, for example, a conventional synthetic green laser. In this package, the laser is first attached to the hybrid 10 using solder. The hybrid is aluminum nitride (AlN) whose CTE (˜4.4 ppm/C) matches that of the GaAs chip (˜6.2 ppm/C) and also has high thermal conductivity (150 W/m-K) to facilitate good thermal management. The chip 14 is wire-bonded to gold pads on the AlN hybrid. Later the chip plus the hybrid is attached to the molybdenum block 16 using solder. The whole stack is then attached to the package base 18.

Apart from the chip, there are three additional components: hybrid, molybdenum block, and package base. In a typical package, there are primarily four process steps: solder attachment between the chip and the hybrid, solder attachment between the hybrid and the molybdenum block, solder attachment between the molybdenum block and the package base, and finally wire-bonding. Each of the components has to be coated separately to facilitate the soldering processes.

Exemplary joining methods disclosed herein uses a bulk metallic glass to form the whole base structure 200 as shown in FIG. 2. FIG. 2 is an illustration of an opto-electronic package using a BMG made according to exemplary methods. “L, W, t” are representative of a particular application. However, these values change depending on the application.

For convenience, this structure is referred to herein as the “BMG package structure”. The composition of the bulk metallic glass 20 can be selected from any system which exhibits good glass formability (large critical thickness). Critical thickness (tmax, in mm) is the maximum thickness that an alloy can be cast into and still remain amorphous. This thickness is related to the critical cooling rate (Rc, in deg K/s) of the alloy (i.e. how fast it must be quenched to be amorphous) through the expression Rc˜1000/tmax². Thus, if a 2 mm thick part is required, the alloy needs to have an Rc˜250 K/sec or for a 3 mm thick part, Rc-100 K/sec) including, for example, Zr-based alloys (e.g. Zr55Al10Ni5Cu30, Zr52.5Cu17.9Ni14.6Al10Ti5), noble metal-based alloys (e.g. Pd40Cu30Ni10P20), Cu-based alloys (e.g. Cu49Zr45Al6) , rare-earth based alloys, and Ti-based alloys.

Further shown in FIG. 2 is a semiconductor chip 22 and Au pads 24 on the BMG. Advantageously, the cost of the BMG material is as low as possible to minimize the bill of materials, the BMG contains no toxic elements or components that outgas, and the Tg of the BMG is higher than the metallization and soldering temperatures used in the packaging process. The BMG package structure can be formed by direct casting of the melt into a mold with sufficient quench rate to form a glassy material (e.g. die casting). Alternatively, a BMG preform can be cast which is then thermoplastically formed into the BMG package structure by reheating the material into the SCLR and forming it to net shape, e.g. compression molding, injection molding. The BMG preform could alternatively be a metallic glass powder which is thermoplastically formed or sintered. The BMG material could alternatively be a composite material containing a glassy phase and second phase particles either added to the material or formed in situ (by crystallization). Such a second phase could be used to control the material's properties, for example, its CTE or thermal conductivity.

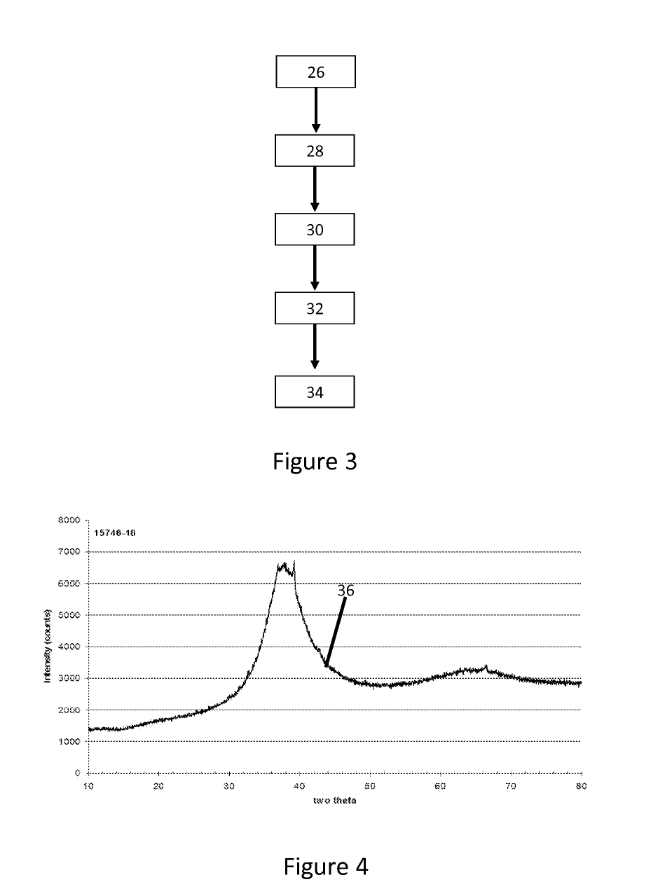

FIG. 3 is an illustration of an exemplary joining method.

One embodiment, an example is shown in FIG. 3, is a method comprising:
providing a bulk metallic glass having at least one surface 26;
applying a contact layer to the at least one surface of the bulk metallic glass 28;
applying a diffusion barrier layer to the contact layer 30;
applying a cap layer to the diffusion barrier layer 32; and
joining a material to the layered bulk metallic glass.

Another embodiment is a bulk metallic glass submount comprising:
a bulk metallic glass having at least one surface;
a contact layer on at least a portion of the at least one surface of the bulk metallic glass;
a diffusion barrier layer on the contact layer; and
a cap layer on the diffusion barrier layer.

An exemplary method for joining a semiconductor chip to the BMG package is as follows: first a surface of the bulk metallic glass onto which the semiconductor chip is to be attached is prepared. The bulk metallic glass is deposited with Cr—Ni coating using, for example, an evaporation technique. An entire surface or a portion of a surface of the bulk metallic glass can be coated. This is followed by nickel flash and then gold coating. For the solderable applications, dull sulfamate nickel deposits can be used. Sulfamate nickel deposits provide the corrosion resistance. After these steps, there are two options, for example, a solder preform can be used or solder can be pre-deposited onto the coated BMG. This can facilitate soldering of the semiconductor chip to the BMG.

In some embodiments, an insulating layer, e.g. SiN, is deposited on the uncoated portion of the BMG surface and Au pads are coated which can serve as pads for wire-bonding. In some embodiments, only one component and two joining process steps (chip-attach to BMG package structure and wire-bonding) are needed and may result in cost savings through reduced bill of materials, process time, and number of steps. The chip reliability will not be compromised if the CTE of the BMG material is tailored to that of semiconductor chip and the thermal conductivity is sufficiently high (e.g. ˜200 W/m-K).

As an example, a bulk metallic glass substrate was formed and joined to a GaAs chip using the disclosed methods. A BMG substrate of a Zr-based metallic glass, Zr52.5Cu17.9Ni14.6Al10Ti5, was made by the following method. Pieces of high purity Zr, Cu, Ni, Al, and Ti wire were weighed in an Ar-purged glovebox. The metals were arc melted in a clean Ar atmosphere on a water-cooled copper hearth to form a button of the alloy. The button was remelted 3-4 times in order to homogenize the material. The alloy button was then re-melted in the arc melter and suction cast into a water-cooled copper mold with dimensions 1.5 mm×8 mm×30 mm. The as-cast BMG was polished on one surface.

FIG. 4 is a graph of an X-ray diffraction analysis of the polished surface of the BMG and shows that the material was amorphous. The X-ray diffraction pattern, Line 36, of the polished surface of the BMG substrate shows a primarily amorphous structure. Small peaks superimposed on the amorphous background can be attributed to a crystalline oxide phase on the BMG substrate surface. The BMG substrate was cut and polished to a 5 mm×5 mm×1 mm thick substrate, one surface having a mirror-like finish, the other surface a rough polished flattened surface.

The Tg of the Vit105 BMG was measured by DSC-TGA as ˜395° C. and Tx (onset) as ˜453° C. The BMG substrate was cleaned and metalized or coated. Next, these BMG substrates were coated with Cr—Ni followed by dull-sulfamate Ni and then Au coated. Eutectic Au—Sn solder preforms were cut into the required shape and sandwiched between the BMG substrate and the semiconductor chip. This multi-layer stack was held tight with the chip and was carefully transferred to a solder reflow oven. The highest temperature in the oven was 320° C. and was cooled down to room temperature. This is because the melting point of the Au—Sn solder is 280° C. Once the bond was formed, the soldered assembly was removed from the solder reflow oven and, as a first step, a needle was poked at the chip to make sure it was strongly adhered to the substrate. Next, one of the assembled samples was loaded into the dage machine and a shear test was performed. The shear force required to shear off the chip was approximately 0.5 Kg.

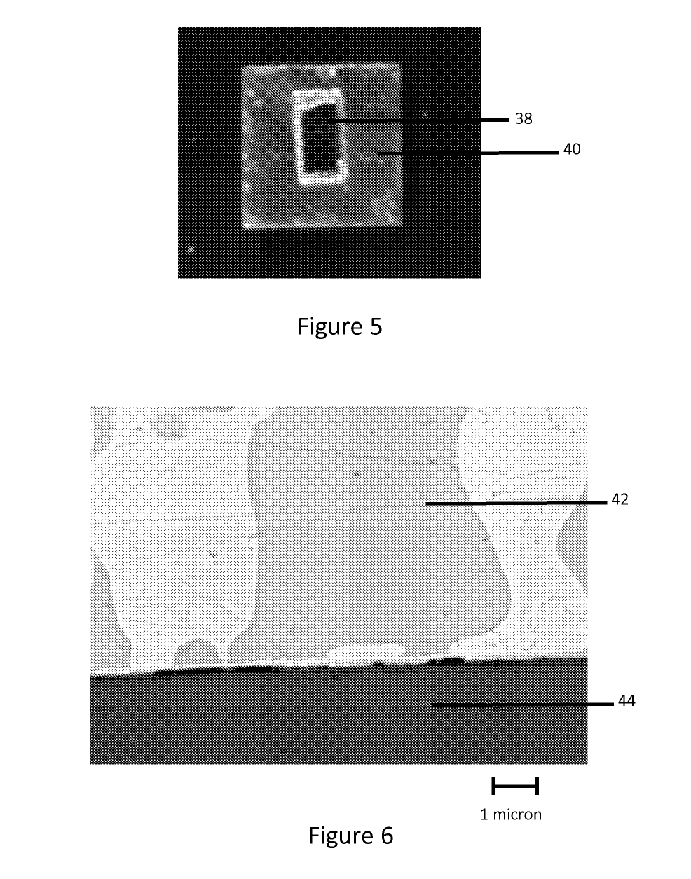

FIG. 5 is an optical photograph of a GaAs chip 38 soldered to a metalized or coated BMG substrate 40.

FIG. 6 is an SEM image of the BMG/metallization+solder interface. FIG. 6 is a backscattered electron image of soldered interface showing adhesion of metallization layers and solder 42 to a BMG substrate 44. The results show that GaAs was successfully soldered to a coated BMG substrate.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. A method comprising:
providing a bulk metallic glass having at least one surface;
applying a contact layer to at least a portion of the at least one surface of the bulk metallic glass;
applying a diffusion barrier layer to the contact layer;
applying a cap layer to the diffusion barrier layer to form a layered bulk metallic glass; and
joining a material to the layered bulk metallic glass.

2. The method according to claim 1, wherein the contact layer comprises chromium and nickel, titanium, palladium, or combinations thereof.

3. The method according to claim 1, wherein the diffusion barrier layer comprises nickel, platinum, palladium, tungsten, or combinations thereof.

4. The method according to claim 1, wherein the cap layer comprises gold, platinum, or a combination thereof.

5. The method according to claim 1, wherein the diffusion barrier layer is comprised of dull-sulfamate nickel.

6. The method according to claim 1, further comprising depositing an insulating layer onto any bare portion of the bulk metallic glass prior to the applying the cap layer.

7. The method according to claim 3, wherein the insulating layer is comprised of silicon nitride, silicon oxynitride or a combination thereof.

8. The method according to claim 1, wherein the joining comprises soldering the material to the layered bulk metallic glass.

9. The method according to claim 5, wherein the soldering comprises using one or more solder preforms.

10. The method according to claim 5, wherein the soldering comprises pre-depositing solder onto the layered bulk metallic glass.

11. The method according to claim 1, wherein the material comprises a cap layer comprising gold.

12. The method according to claim 1, wherein the providing the bulk metallic glass comprises casting of a melt of the bulk metallic glass into a mold.

13. The method according to claim 1, wherein the providing the bulk metallic glass comprises casting the bulk metallic glass and thermoplastically forming the bulk metallic glass.

14. The method according to claim 1, wherein the providing the bulk metallic glass comprises forming or sintering a metallic glass powder.

15. The method according to claim 1, wherein the bulk metallic glass is a composite material comprising a metallic glass phase and one or more crystalline phases, amorphous phases, or combinations thereof.

16. A bulk metallic glass submount comprising:
a bulk metallic glass having at least one surface;
a contact layer on at least a portion of the at least one surface of the bulk metallic glass;
a diffusion barrier layer on the contact layer; and
a cap layer on the diffusion barrier layer.

17. An electronic package comprising the bulk metallic submount according to claim 16.

18. The package according to claim 17, wherein the package is an LED or a semiconductor laser package.

19. The glass according to claim 17, wherein the bulk metallic glass is a composite material comprising a metallic glass phase and one or more crystalline phases, amorphous phases, or combinations thereof.
